(19) United States
(12) Patent Application Publication
(10) Pub. No.: US 2025/0149397 A1
(43) Pub. Date: May 8, 2025

(54) SEMICONDUCTOR DEVICE INCLUDING HEATING STRUCTURE

(71) Applicant: SAMSUNG ELECTRONICS CO., LTD., SUWON-SI (KR)

(72) Inventors: Seonhaeng LEE, Suwon-si (KR); Gangjun KIM, Suwon-si (KR)

(21) Appl. No.: 18/732,276

(22) Filed: Jun. 3, 2024

(30) Foreign Application Priority Data
Nov. 2, 2023 (KR) 10-2023-0149921

(51) Int. Cl. H01L 23/34; H01L 23/528; H01L 23/532; H10B 12/00

(52) U.S. Cl. CPC H01L 23/345; H01L 23/5283; H01L 23/53209; H10B 12/50

(57) ABSTRACT

A semiconductor device includes a substrate having a device region including a memory cell region and a peripheral circuit region, and a heating region surrounding the device region, a heating structure disposed in the heating region of the substrate, the heating structure surrounding the device region in a plan view, and a temperature control device electrically connected to the heating structure. The peripheral circuit region includes a peripheral gate structure. The heating structure includes a first lower structure disposed at about a same level as the peripheral gate structure. The first lower structure includes a lower dielectric layer, and a conductive layer including polysilicon disposed on the lower dielectric layer.

### CROSS-REFERENCE TO RELATED APPLICATION(S)

This application claims priority under 35 U.S.C. § 119 to Korean Patent Application No. 10-2023-0149921, filed on Nov. 2, 2023 in the Korean Intellectual Property Office, the disclosure of which is incorporated by reference herein in its entirety.

### TECHNICAL FIELD

Embodiments of the present inventive concept relate to a semiconductor device including a heating structure.

### DISCUSSION OF RELATED ART

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is desirable to implement patterns having a fine width or a fine separation distance. The operating properties of semiconductor devices may vary depending on temperature changes, leading to operational errors or reduced data reliability during data recording and/or reading.

### SUMMARY

Embodiments of the present inventive concept provide a semiconductor device including a heating structure surrounding a device region.

According to an embodiment of the present inventive concept, a semiconductor device includes a substrate having a device region including a memory cell region and a peripheral circuit region, and a heating region surrounding the device region, a heating structure disposed in the heating region of the substrate, the heating structure surrounding the device region in a plan view, and a temperature control device electrically connected to the heating structure. The peripheral circuit region includes a peripheral gate structure. The heating structure includes a first lower structure disposed at a about a same level as the peripheral gate structure. The first lower structure includes a lower dielectric layer, and a conductive layer including polysilicon disposed on the lower dielectric layer.

According to an embodiment of the present inventive concept, a semiconductor device includes a substrate having a device region including a memory cell region and a peripheral circuit region, and a heating region surrounding the device region, at least one heating structure disposed in the heating region of the substrate, the at least one heating structure surrounding the device region in a plan view, and at least one temperature control device electrically connected to the at least one heating structure. The peripheral circuit region includes a peripheral gate structure. The peripheral gate structure includes a gate dielectric layer and a gate electrode disposed on the gate dielectric layer. The at least one heating structure includes first lower structures disposed at a same level as the peripheral gate structure. The first lower structures each include a lower dielectric layer and a conductive layer disposed on the lower dielectric layer, the conductive layer and the gate electrode including a same material. A thickness of a lower dielectric layer of at least one of the first lower structures is different from a thickness of the gate dielectric layer.

According to an embodiment of the present inventive concept, a semiconductor device includes a substrate having a device region including a memory cell region and a peripheral circuit region, and a heating region surrounding the device region, the peripheral circuit region including a peripheral gate structure, a heating structure disposed in the heating region of the substrate, the heating structure surrounding the device region in a plan view and including first lower structures disposed at a same level as the peripheral gate structure, capping layers covering the first lower structures, spacers covering side surfaces of the capping layers and the first lower structures, first lower contacts passing through the capping layers, the first lower contacts electrically connected to the first lower structures, a gate capping layer covering the peripheral gate structure, a gate contact passing through the gate capping layer, the gate contact electrically connected to the peripheral gate structure, and a temperature control device electrically connected to the heating structure. The first lower structures each include a lower dielectric layer, and a conductive layer including polysilicon disposed on the lower dielectric layer. The first lower contacts are electrically connected to the temperature control device and electrically isolated from the gate contact.

### BRIEF DESCRIPTION OF THE DRAWINGS

The above and other features of the present inventive concept will become more apparent by describing in detail embodiments thereof with reference to the accompanying drawings, in which:

FIG. 1 is a plan view of a semiconductor device according to an example embodiment;

FIG. 2 is a schematic plan view of a device region of a semiconductor device according to an example embodiment;

FIG. 3 schematically illustrates a memory cell of a bank array of a semiconductor device according to an example embodiment;

FIG. 4 is a vertical cross-sectional view of a semiconductor device according to an example embodiment;

FIG. 5 is a perspective view of a first lower structure illustrated in FIG. 4;

FIGS. 6 to 8 are perspective views of a semiconductor device according to example embodiments;

FIG. 9 is a plan view of a semiconductor device according to an example embodiment;

FIG. 10 is a vertical cross-sectional view of the semiconductor device illustrated in FIG. 9;

FIG. 11 is a perspective view of a heating structure illustrated in FIG. 10;

FIG. 12 is a vertical cross-sectional view of a semiconductor package including a semiconductor device according to an example embodiment;

FIG. 13 is an enlarged view of the semiconductor device illustrated in FIG. 12;

FIG. 14 is a vertical cross-sectional view of a semiconductor package including a semiconductor device according to an example embodiment;

FIGS. 15 to 17 are plan views of a semiconductor device according to example embodiments;

FIG. 18 is a schematic diagram of a temperature control device according to an example embodiment; and

FIG. 19 is a flowchart illustrating a temperature control method according to an example embodiment.

### DETAILED DESCRIPTION

Embodiments of the present inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an example embodiment may be described as a “second” element in another example embodiment.

It should be understood that descriptions of features or aspects within each example embodiment should typically be considered as available for other similar features or aspects in other example embodiments, unless the context clearly indicates otherwise.

As used herein, the singular forms “a”, “an” and “the” are intended to include the plural forms as well, unless the context clearly indicates otherwise.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion. For example, when two elements are described as being disposed at about a same level, the two elements may be disposed exactly at the same level, or approximately at the same level within a measurement error.

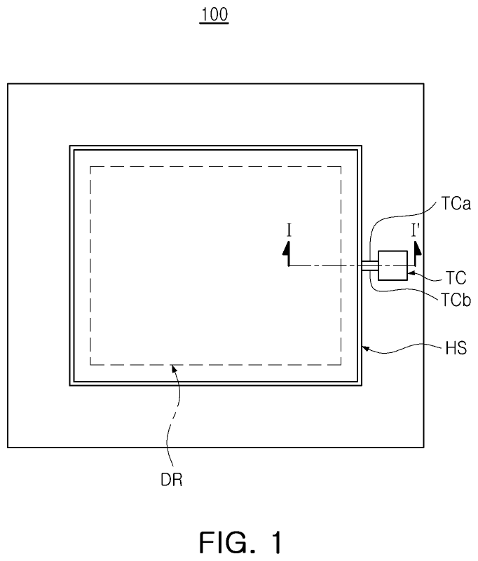

FIG. 1 is a plan view of a semiconductor device according to an example embodiment.

Referring to FIG. 1, a semiconductor device 100 according an example embodiment may be a memory chip. The memory chip may include a volatile memory chip such as, for example, a dynamic random access memory (DRAM) or a static random access memory (SRAM), or a non-volatile memory chip such as, for example, a phase-change random access memory (PRAM), a magnetoresistive random access memory (MRAM), a ferroelectric random access memory (FeRAM), a resistive random access memory (RRAM), or a NAND flash. In an example embodiment, the semiconductor device 100 may be a DRAM chip.

The semiconductor device 100 may include a heating structure HS surrounding a device region DR, and a temperature control device TC electrically connected to the heating structure HS. The temperature control device TC may be electrically connected to the heating structure HS through input/output terminals TCa and TCb.

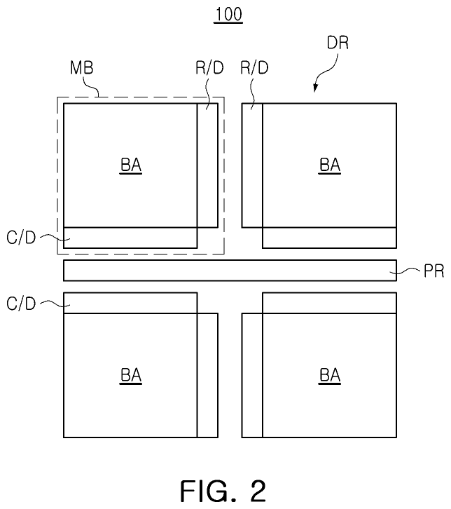

FIG. 2 is a schematic plan view of a device region of a semiconductor device according to an example embodiment.

Referring to FIG. 2, the device region DR of the semiconductor device 100 according to an example embodiment of the present inventive concept may include a memory bank MB and a peripheral region PR. The memory bank MB may include a bank array BA having a plurality of memory cells, a row decoder R/D, a column decoder C/D, and the like. The memory bank MB may further include a sense amplifier disposed adjacent to the column decoder C/D. In an example embodiment, the semiconductor device 100 may include a plurality of memory banks MB.

The plurality of memory banks MB included in the semiconductor device 100 may share one peripheral region PR. Peripheral circuits for input/output of data or commands, or input of power/ground, may be disposed in the peripheral region PR. The peripheral region PR may read data from or write data to the memory banks MB. In addition, the peripheral region PR may specify an address to store data or determine an operation mode of the semiconductor device 100. In addition, the peripheral region PR may include an input/output pad that transmits data to be stored in the plurality of memory banks MB and data output by the plurality of memory banks MB.

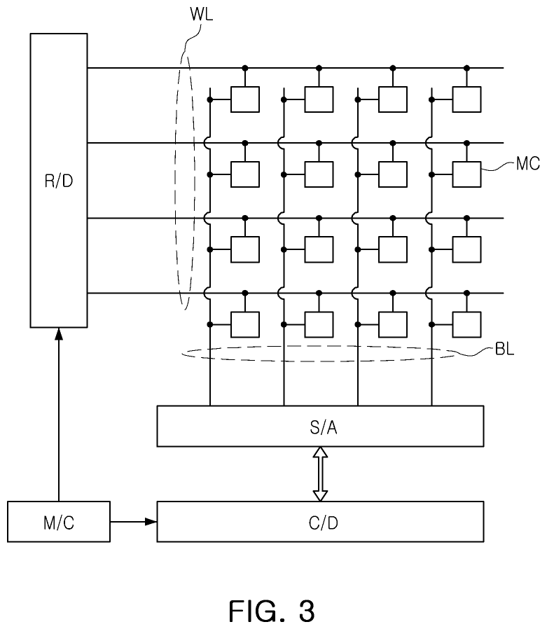

FIG. 3 schematically illustrates a memory cell of a bank array of a semiconductor device according to an example embodiment.

A connection relationship and operations between the memory cells of the bank array BA and peripheral circuits and/or core circuits disposed on the periphery thereof will be described in more detail with reference to FIG. 3. A word line WL and a bit line BL for an operation such as reading and writing of memory cells MC may be connected to the memory cells MC. The word line WL and the bit line BL may extend in a direction in which the word line WL and the bit line BL intersect each other.

Each row of the memory cells MC may be connected to the word line WL. In addition, each column of the memory cells MC may be connected to the bit line BL. One word line WL and one bit line BL may be activated, for example, a voltage may be applied to a corresponding word line WL and a corresponding bit line BL, thereby accessing one memory cell corresponding to an intersection point thereof.

The row decoder R/D may receive a row address from a memory controller M/C and activate, based on the received row address, an appropriate word line WL. Similarly, the column decoder C/D may receive a column address from the memory controller M/C, and may activate an appropriate bit line BL. The memory controller M/C may be disposed, for example, in the peripheral region PR. A sense amplifier S/A may be disposed adjacent to the column decoder C/D in the peripheral region PR.

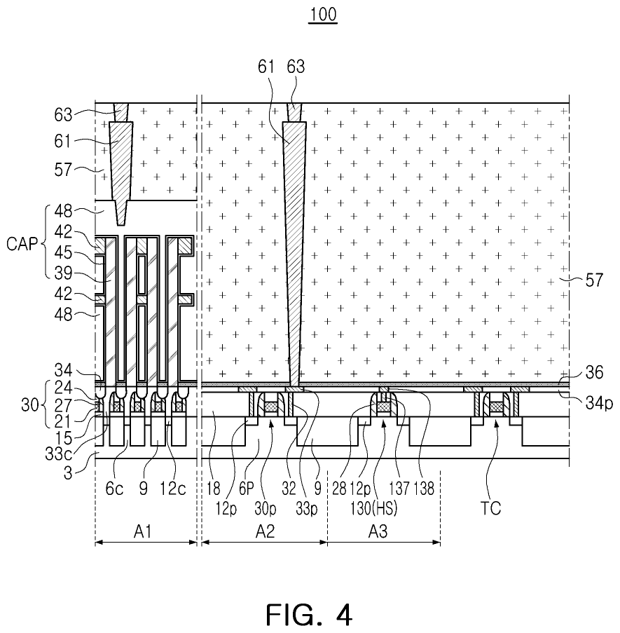

FIG. 4 is a vertical cross-sectional view of a semiconductor device according to an example embodiment.

In an example embodiment, a substrate 3 of the semiconductor device 100 may have a memory cell region A1, a peripheral circuit region A2, and a heating region A3. The memory cell region A1 may include the bank array BA illustrated in FIGS. 2 and 3, and the peripheral circuit region A2 may include a row decoder R/D, a sense amplifier S/A, a column decoder C/D, and a peripheral region PR. The device region DR illustrated in FIGS. 1 and 2 may have a memory cell region A1 and a peripheral circuit region A2.

In the memory cell region A1, the semiconductor device 100 may include a substrate 3 having cell active regions 6c, a device isolation layer 9 defining the cell active regions 6c in the substrate 3, a bit line structure 30 disposed on the substrate 3, the bit line structure 30 including a bit line 21, and an information storage structure CAP disposed on the bit line structure 30. In the memory cell region A1, the semiconductor device 100 may further include cell impurity regions 12c disposed on the cell active region 6c, cell contact plugs 33c disposed on the cell impurity regions 12c, and an insulating pattern 34 disposed between the cell contact plugs 33c.

The bit line 21 may correspond to the bit line BL illustrated in FIG. 3. The semiconductor device 100 may further include a word line (corresponding to WL in FIG. 3) disposed in the memory cell region A1, the word line being buried in the substrate 3.

The substrate 3 may include a semiconductor material, such as, for example, a group IV semiconductor, a group III-V compound semiconductor, or a group II-VI compound semiconductor. For example, the group IV semiconductor may include silicon, germanium, or silicon-germanium. The substrate 3 may further include impurities. The substrate 3 may be, for example, a silicon substrate, a silicon-on-insulator (SOI) substrate, a germanium substrate, a germanium-on-insulator (GOI) substrate, a silicon-germanium substrate, or a substrate including an epitaxial layer.

The cell active regions 6c may be defined in the substrate 3 by the device isolation layer 9. The cell active regions 6c may have cell impurity regions 12c having a predetermined depth from an upper surface of the substrate 3. The cell impurity regions 12c may be spaced apart from each other. The cell impurity regions 12c may serve as source and drain regions of a transistor formed by the word line. The source region and the drain region may be formed by the cell impurity regions 12c using doping of substantially the same impurities or ion implantation, and may be interchangeably referred to depending on a circuit configuration of a finally formed transistor. The impurities may include impurities having a conductivity type opposite to that of the substrate 101.

The device isolation layer 9 may be formed using a shallow trench isolation (STI) process. The device isolation layer 9 may surround the cell active regions 6c, and may electrically isolate the cell active regions 6c from each other. The device isolation layer 9 may be formed of an insulating material such as, for example, silicon oxide, silicon nitride, or a combination thereof.

The word line may be disposed to cross the cell active regions 6c. For example, a pair of word lines adjacent to each other may be disposed to cross one cell active region 6c. The word line may form a gate of a buried channel array transistor (BCAT), but the present inventive concept is not limited thereto.

Bit line structures 30 may be disposed on a first lower insulating layer 15. Each of the bit line structures 30 may include bit lines 21, bit line capping layers 24 disposed on the bit lines 21, and bit line spacers 27 disposed on side surfaces of the bit lines 21 and the bit line capping layers 24.

The bit lines 21 may include a conductive material. For example, the bit lines 21 may include a semiconductor material such as polysilicon, a metal-semiconductor compound, a metal material, or combinations thereof. The metal-semiconductor compound may include, for example, cobalt silicide (CoSi), titanium silicide (TiSi), nickel silicide (NiSi), tungsten silicide (WSi), or other metal silicide. The metal material may include, for example, titanium (Ti), tantalum (Ta), tungsten (W), aluminum (Al), or combinations thereof. The bit line capping layers 24 may be formed of an insulating material such as, for example, silicon nitride. The bit line spacers 27 may be formed of an insulating material such as, for example silicon nitride. In an example embodiment, the semiconductor material may be doped with impurities.

The cell contact plugs 33c may be disposed between the bit line structures 30, and may be electrically connected to the cell impurity regions 12c in the cell active regions 6c. Insulating patterns 34 may be disposed between the cell contact plugs 33c. The insulating patterns 34 may include an insulating material, and may electrically insulate the cell contact plugs 33c from each other.

The cell active regions 6c, the word line, and the cell contact plugs 33c may form a memory cell (MC in FIG. 3). The information storage structure CAP may be disposed on the memory cell. The information storage structure CAP may include a lower electrode 39, support patterns 42, a dielectric layer 45, and an upper electrode 48.

The lower electrode 39 may include a conductive material such as, for example, metal, metal nitride, metal oxide, metal silicite, conductive carbon, or combinations thereof. For example, the lower electrode 39 may include Ti, TiN, TiAlN, TiCN, Ta, TaN, TaAlN, TaCN, Ru, Pt, or combinations thereof. In example embodiments, each of the lower electrodes 39 may have a pillar shape extending in a direction substantially perpendicular to the upper surface of the substrate 3. However, the shape of the lower electrode 39 is not limited thereto, and may have, for example, a cylindrical shape, a planar shape, or the like.

The support patterns 42 may be disposed on a side surface of the lower electrode 39 to connect adjacent lower electrodes 39 to each other. The support patterns 42 may prevent defects such as collapse or deformation of the pillar-shaped lower electrode 39.

The dielectric layer 45 may be conformally disposed along surfaces of the lower electrode 39 and the support patterns 42. The dielectric layer 45 may include, for example, a high-κ dielectric, silicon oxide, silicon nitride, silicon oxynitride, or combinations thereof.

The upper electrode 48 may fill a space between the lower electrodes 39 on the dielectric layer 45, and may cover the lower electrode 39 and the support patterns 42. The upper electrode 48 may include a conductive material such as, for example, metal, metal nitride, conductive carbon, a conductive semiconductor compound, or combinations thereof. The semiconductor compound may include a doped SiGe material.

The information storage structure CAP may be a DRAM cell capacitor capable of storing information in a memory cell array such as DRAM. For example, the lower electrode 39 may be a lower electrode or a storage node of the DRAM cell capacitor, and the upper electrode 48 may be an upper electrode or a plate electrode of the DRAM cell capacitor. The semiconductor device 100 may further include a lower etch stop layer 36 disposed below the information storage structure CAP. The lower electrode 39 may pass through the lower etch stop layer 36 to be in contact with the cell contact plug 33c. The information storage structure CAP may be electrically connected to the cell impurity regions 12c through cell contact plugs 33c.

The semiconductor device 100 may further include an interlayer insulating layer 57 covering the information storage structure CAP, a first contact structure 61 connected to the information storage structure CAP, and contacts 63 connected to the first contact structures 61. In the memory cell region A1, the first contact structure 61 may pass through the interlayer insulating layer 57 to be connected to the information storage structure CAP. The contacts 63 may be electrically connected to the first contact structures 61.

In the peripheral circuit region A2, the semiconductor device 100 may further include peripheral active regions 6p, a peripheral impurity region 12p disposed on the peripheral active regions 6p, and a peripheral gate structure 30p disposed on the substrate 3. The peripheral active regions 6p may be defined by device isolation layers 9. The peripheral impurity regions 12p may be disposed adjacent to the peripheral gate structure 30p. In an example embodiment, the peripheral gate structure 30p may have a structure the same as or similar to that of the bit line structure 30.

In the peripheral circuit region A2, the semiconductor device 100 may further include a second lower insulating layer 18 covering the substrate 3, a peripheral contact plug 32 disposed adjacent to the peripheral gate structure 30p, a peripheral interconnection 33p connected to the peripheral contact plug 32, and an insulating pattern 34p covering a side surface of the peripheral interconnection 33p.

The peripheral contact plug 32 may pass through the second lower insulating layer 18 to be in contact with the peripheral impurity region 12p. The peripheral interconnection 33p may be disposed on the peripheral contact plug 32, and may be electrically connected to the peripheral impurity region 12p through the peripheral contact plug 32. The peripheral contact plug 32 and the peripheral interconnection 33p may include a metal material, and the metal material may include, for example, titanium (Ti), tantalum (Ta), tungsten (W), aluminum (Al), or combinations thereof. The insulating pattern 34p may cover the second lower insulating layer 18 and the peripheral gate structure 30p.

In the peripheral circuit region A2, the first contact structure 61 and the contact 63 may also be disposed. For example, the first contact structure 61 may pass through the interlayer insulating layer 57 to be in contact with the peripheral interconnection 33p.

In the heating region A3, the semiconductor device 100 may include a first lower structure 130 disposed on the substrate 3. The first lower structure 130 may form the heating structure HS illustrated in FIG. 1. The heating region A3 may extend along the heating structure HS illustrated in FIG. 1, and may surround the device region DR having the memory cell region A1 and the peripheral circuit region A2.

In an example embodiment, the first lower structure 130 may be disposed at a level about the same as those of the bit line structure 30 of the memory cell region A1 and the peripheral gate structure 30p of the peripheral circuit region A2. For example, the first lower structure 130 may have a structure the same as or similar to those of the bit line structure 30 and the peripheral gate structure 30p.

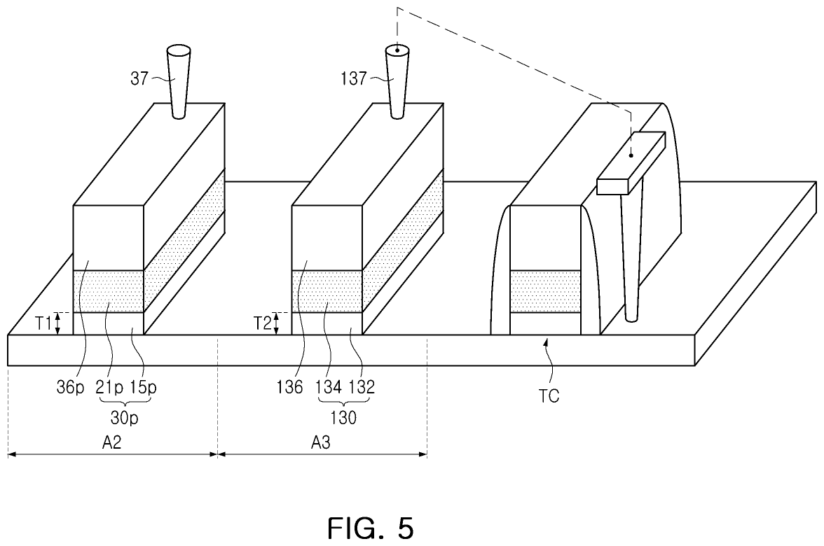

FIG. 5 is a perspective view of the first lower structure illustrated in FIG. 4.

Referring to FIG. 5, the peripheral gate structure 30p may include a gate dielectric layer 15p and a gate electrode 21p disposed on the gate dielectric layer 15p. The gate dielectric layer 15p may include, for example, a high-κ dielectric, silicon oxide, silicon nitride, silicon oxynitride, or combinations thereof. The gate electrode 21p may include a material the same as that of the bit line 21. For example, the gate electrode 21p may include a semiconductor material such as polysilicon. The polysilicon may be doped, and may have an N-type conductivity type or P-type conductivity type. For example, the polysilicon may include an N-type impurity such as phosphorus (P), arsenic (As), or antimony (Sb) or a P-type impurity such as boron (B). In an example embodiment, the gate electrode 21p may further include a metal material on polysilicon and a metal-semiconductor compound disposed between the polysilicon and the metal material.

The first lower structure 130 may include a lower dielectric layer 132 and a conductive layer 134 disposed on the lower dielectric layer 132. The lower dielectric layer 132 may be disposed at a level about the same as that of the gate dielectric layer 15p. For example, a lower surface of the lower dielectric layer 132 and a lower surface of the gate dielectric layer 15p may be disposed at about the same level. The lower dielectric layer 132 may include a material the same as that of the gate dielectric layer 15p, for example, high-κ dielectric, silicon oxide, silicon nitride, silicon oxynitride, or combinations thereof. A thickness T2 of the lower dielectric layer 132 is illustrated as being the same as a thickness T1 of the gate dielectric layer 15p, but the present inventive concept is not limited thereto. For example, in some example embodiments, the thickness T2 of at least one of the lower dielectric layers 132 may be greater than the thickness T1 of the gate dielectric layer 15p, which may result in heating the first lower structure 130 to a higher temperature.

The conductive layer 134 may include a conductive material such as, for example, polysilicon. An impurity concentration of polysilicon of the conductive layer 134 may be lower than an impurity concentration of polysilicon of the gate electrode 21p. For example, a doping process may not be performed on polysilicon of the conductive layer 134, and the polysilicon may be undoped polysilicon. The conductive layer 134 may include undoped polysilicon, and thus may have specific resistance higher than that of the gate electrode 21p including doped polysilicon.

The semiconductor device 100 may further include a gate capping layer 36p disposed on the peripheral gate structure 30p, a capping layer 136 disposed on the first lower structure 130, and spacers 28 covering side surfaces of the peripheral gate structure 30p and the first lower structure 130. The capping layer 36p and the capping layer 136 may be disposed at a level about the same as that of the bit line capping layer 24. For example, upper surfaces of the capping layer 36p and the capping layer 136 may be disposed at a level about the same as that of an upper surface of the bit line capping layer 24. The capping layer 36p and the capping layer 136 may include a material the same as that of the bit line capping layer 24 such as, for example, silicon nitride.

Side surfaces of the peripheral gate structure 30p and the gate capping layer 36p may be covered by a corresponding spacer 28. Side surfaces of the first lower structure 130 and the capping layer 136 may be covered by a corresponding spacer 28. The spacers 28 may include a material the same as that of the bit line spacers 27.

The semiconductor device 100 may further include a gate contact 37 electrically connected to the peripheral gate structure 30p, a first lower contact 137 electrically connected to the first lower structure 130, and a conductive interconnection 138 disposed on the first lower contact 137. The gate contact 37 may pass through the gate capping layer 36p to be in contact with the gate electrode 21p. The gate contact 37 may be electrically connected to the corresponding first contact structure 61.

The first lower contact 137 may pass through the capping layer 136 to be in contact with the conductive layer 134. The conductive interconnection 138 may be disposed on the first lower contact 137. The first lower contact 137 may be electrically connected to the corresponding temperature control device TC. For example, the first lower contact 137 may be electrically connected to input/output terminals Tca and TCb of the temperature control device TC illustrated in FIG. 1. The first lower structure 130 may be electrically insulated from the memory cell region A1 or the peripheral circuit region A2. For example, the first lower structure 130 may be isolated from the bit line structure 30 and the peripheral gate structure 30p without being electrically connected to the bit line structure 30 and the peripheral gate structure 30p.

As illustrated in FIG. 1, the heating structure HS including the first lower structure 130 may be disposed to surround the device region DR having the memory cell region A1 and the peripheral circuit region A2.

In an example embodiment, as illustrated in FIG. 1, the temperature control device TC may be disposed outside of the heating region A3. For ease of description, the temperature control device TC is illustrated as a single transistor, but the temperature control device TC is not limited thereto. For example, the temperature control device TC may include an active device such as a transistor or a diode, and a passive device such as a resistor or a capacitor. The temperature control device TC may be disposed at a level about the same as those of the bit line structure 30, the peripheral gate structure 30p, and the first lower structure 130. For example, upper and lower surfaces of the temperature control device TC may be disposed at a level about the same as those of upper and lower surfaces of the bit line structure 30, the peripheral gate structure 30p, and the first lower structure 130.

The temperature control device TC may be electrically connected to the first lower structure 130. However, the temperature control device TC may be electrically insulated from the memory cell region A1 or the peripheral circuit region A2. For example, the temperature control device TC may be isolated from the bit line structure 30 and the peripheral gate structure 30p without being electrically connected to the bit line structure 30 and the peripheral gate structure 30p. The first lower structure 130 may be heated by the temperature control device TC to increase a temperature of the device region DR. Read and write operations of a semiconductor device or electrical switching properties of a transistor may be changed in a low-temperature environment. However, the temperature control device TC according to embodiments of the present inventive concept may heat the device region DR to have desired electrical properties, which may increase reliability of the semiconductor device 100.

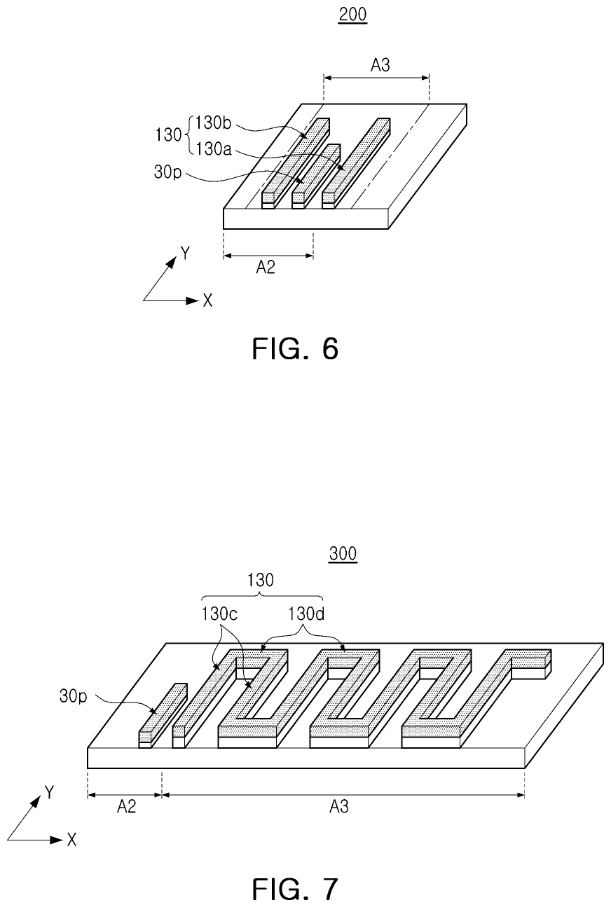

FIGS. 6 to 8 are perspective views of a semiconductor device according to example embodiments. FIGS. 6 to 8 illustrate a peripheral gate structure 30p and a first lower structure 130.

Referring to FIG. 6, a semiconductor device 200 may include a peripheral gate structure 30p disposed in a peripheral circuit region A2 and a first lower structure 130 disposed in a heating region A3. In FIG. 6, the peripheral circuit region A2 and the heating region A3 may extend in a Y-direction.

In an example embodiment, the heating region A3 may partially overlap the peripheral circuit region A2. For example, the first lower structure 130 may include line structures 130a and 130b spaced apart from each other in an X-direction, intersecting a direction in which the heating region A3 extends. The line structures 130a and 130b may be disposed in parallel with the peripheral gate structure 30p with the peripheral gate structure 30p interposed therebetween. The line structure 130a may be disposed on the outside of the peripheral circuit region A2, but the line structure 130b may be disposed in the peripheral circuit region A2.

Referring to FIG. 7, a semiconductor device 300 may include a peripheral gate structure 30p disposed in a peripheral circuit region A2, and a first lower structure 130 disposed in a heating region A3. In an example embodiment, the first lower structure 130 may be disposed in a zigzag manner, and may extend in an X-direction, intersecting a direction in which the heating region A3 extends. For example, the first lower structure 130 may include line structures 130c extending in a Y-direction, and connection structures 130d connecting the line structures 130c to each other.

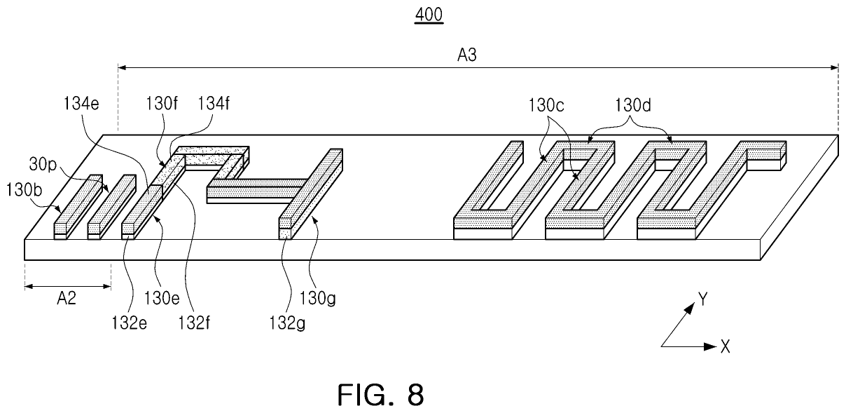

Referring to FIG. 8, a semiconductor device 400 may include a peripheral gate structure 30p disposed in a peripheral circuit region A2, and a first lower structure 130 disposed in a heating region A3. In an example embodiment, the first lower structure 130 may include line structures 130e, 130f, and 130g. Lower dielectric layers of the line structures 130e, 130f, and 130g may have different thicknesses. For example, thicknesses of lower dielectric layers 132e and 132f of the line structures 130e and 130f may be less than a thickness of a lower dielectric layer 132g of the line structures 130g.

Conductive layers 134e and 134f of the line structures 130e and 130f may include polysilicon having impurities having different conductivity types. For example, the conductive layer 134e may include an N-type impurity, and the conductive layer 134f may include a P-type impurity.

As illustrated in FIG. 8, the first lower structure 130 may have locally changed resistance by changing a thickness of a lower dielectric layer and a type of an impurity included in a conductive layer. For example, the first lower structure 130 may include a first portion and a second portion, and the first portion may have a specific resistance higher than that of the second portion.

The semiconductor device 400 may further include a line structure 130b, line structures 130c, and connection structures 130d. The line structure 130b may be disposed in the peripheral circuit region A2.

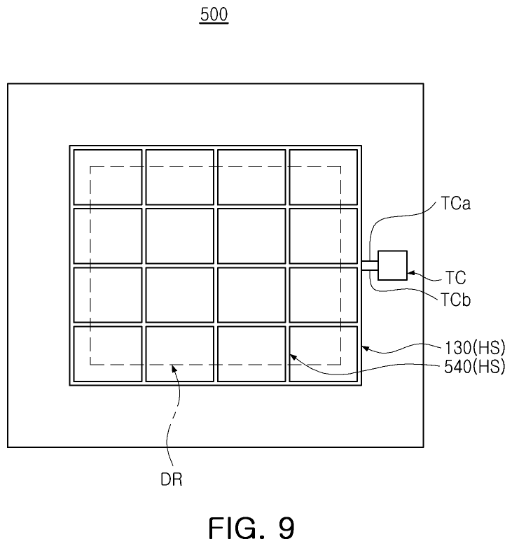

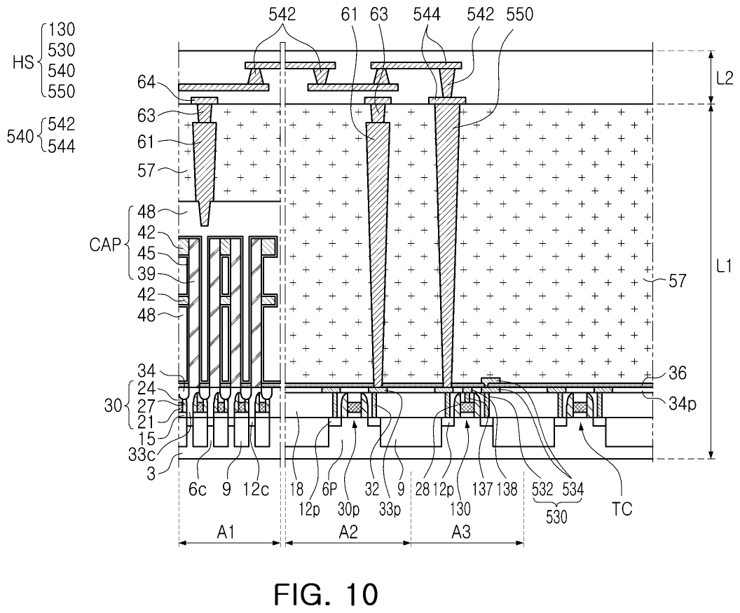

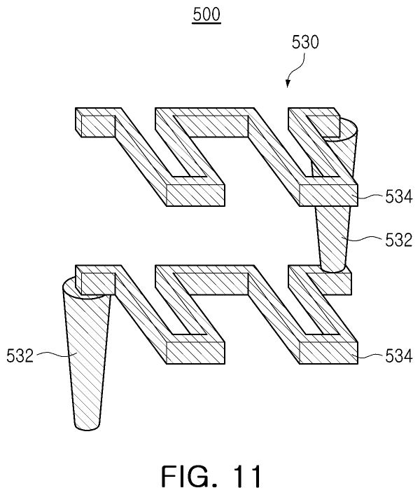

FIG. 9 is a plan view of a semiconductor device according to an example embodiment. FIG. 10 is a vertical cross-sectional view of the semiconductor device illustrated in FIG. 9. FIG. 11 is a perspective view of the heating structure illustrated in FIG. 10. FIG. 11 illustrates a second lower structure.

Referring to FIGS. 9 to 11, a semiconductor device 500 may include a heating structure HS overlapping a device region DR in a vertical direction. For example, a portion of the heating structure HS may extend across the device region DR.

In an example embodiment, the heating structure HS may include a first lower structure 130, a second lower structure 530, an upper structure 540, and a vertical structure 550. The second lower structure 530 may include second lower contacts 532 and lower interconnections 534. The lower interconnections 534 may extend in a horizontal direction, and may be disposed in a plurality of layers. The second lower contacts 532 may vertically extend to be connected to the lower interconnections 534. The second lower contacts 532 may be disposed between the lower interconnections 534, or may be in contact with a peripheral impurity region 12p. Some lower interconnections, among the lower interconnections 534, may be disposed at a level about the same as that of peripheral interconnections 33p, and upper surfaces of some lower interconnections, among the lower interconnections 534, may be disposed at a level about the same as that of upper surfaces of cell contact plugs 33c. The second lower structure 530 may be electrically connected to a temperature control device TC. The second lower structure 530 may be electrically insulated from a memory cell region A1 or a peripheral circuit region A2. For example, the second lower structure 530 may be isolated from a bit line structure 30 and a peripheral gate structure 30p without being electrically connected to the bit line structure 30 and the peripheral gate structure 30p. The second lower contacts 532 and the lower interconnections 534 may include a metal material such as, for example, titanium (Ti), tantalum (Ta), tungsten (W), aluminum (Al), or combinations thereof.

The semiconductor device 500 may include a device layer L1 and an interconnection layer L2 vertically overlapping the device layer L1. For example, the interconnection layer L2 may be disposed on the device layer L1. The upper structure 540 may be disposed in the interconnection layer L2. In the device layer L1, cell active regions 6c, the bit line structures 30, the cell contact plugs 33c, an information storage structure CAP, the peripheral gate structure 30p, the first lower structure 130, the second lower structure 530, and the temperature control device TC may be disposed.

The upper structure 540 may include upper contacts 542 and upper interconnections 544. For example, the upper interconnections 544 may be disposed in a plurality of layers, and may extend in the horizontal direction. The upper contacts 542 may electrically connect the upper interconnections 544 to each other. The upper structure 540 may extend from a heating region A3 to the memory cell region A1 and the peripheral circuit region A2. For example, in a plan view, the upper structure 540 may extend across the device region DR having the memory cell region A1 and the peripheral circuit region A2 in the horizontal direction.

The vertical structure 550 may extend in the vertical direction, may pass through an interlayer insulating layer 57, and may electrically connect the second lower structure 530 and the upper structure 540 to each other. The upper structure 540 may be electrically connected to the temperature control device TC through the vertical structure 550 and the second lower structure 530. The second lower structure 530, the upper structure 540, and the vertical structure 550 may be heated by the temperature control device TC to increase a temperature of the device region DR.

The upper contacts 542, the upper interconnections 544, and the vertical structure 550 may include a metal material such as, for example, titanium (Ti), tantalum (Ta), tungsten (W), aluminum (Al), or combinations thereof.

The semiconductor device 500 may be disposed on the interconnection layer L2, and may further include conductive interconnections 64 electrically connected to the memory cell region A1 or the peripheral circuit region A2. For example, the conductive interconnections 64 may be electrically connected to the information storage structure CAP and the peripheral gate structure 30p through first contact structures 61 and contacts 63. However, in an example embodiment, the conductive interconnections 64 are not electrically connected to the upper structure 540 and the vertical structure 550.

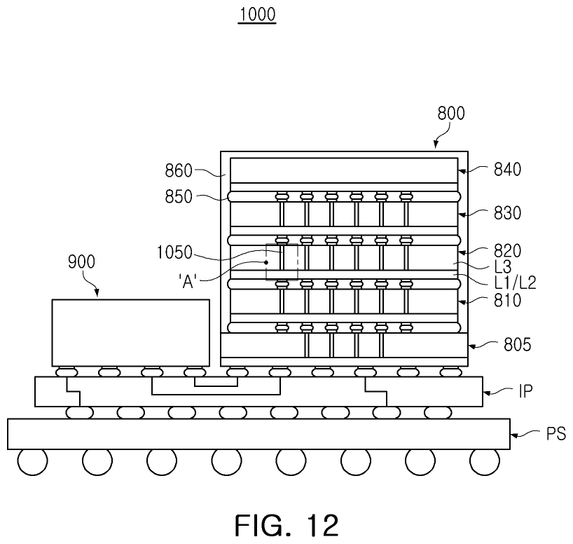

FIG. 12 is a vertical cross-sectional view of a semiconductor package including a semiconductor device according to an example embodiment.

Referring to FIG. 12, a semiconductor package 1000 according to an example embodiment may be a high bandwidth memory (HBM) package. The semiconductor package 1000 may include a package substrate PS, an interposer IP mounted on the package substrate PS, a memory package 800 mounted on the interposer IP, and a processor chip 900. The interposer IP may electrically connect the memory package 800 and the processor chip 900 to each other.

The memory package 800 may include a buffer chip 805, a first semiconductor device 810, a second semiconductor device 820, a third semiconductor device 830, and a fourth semiconductor device 840 that are sequentially stacked.

In an example embodiment, the buffer chip 805 may be a semiconductor device having a type different from those of the first to fourth semiconductor devices 810, 820, 830, and 840. For example, the buffer chip 805 may be a logic chip, and the first to fourth semiconductor devices 810, 820, 830, and 840 may be memory chips. The logic chip may include a microprocessor, analog device, or digital signal processor.

The memory package 800 may further include an adhesive layer 850 and an encapsulant 860. The adhesive layer 850 may be disposed between the buffer chip 805 and the first semiconductor device 810 and between the first to fourth semiconductor devices 810, 820, 830, and 840. The adhesive layer 850 may be a non-conductive film (NCF) or a non-conductive paste (NCP). The encapsulant 860 may be a resin including an epoxy or polyimide. For example, the resin may include a bisphenol-based epoxy resin, a polycyclic aromatic epoxy resin, an o-cresol novolac epoxy resin, a biphenyl-based epoxy resin, or a naphthalene-based epoxy resin.

The processor chip 900 may be, for example, a central processing unit (CPU), a graphics processing unit (GPU), a mobile application, or a digital signal processor (DSP) chip.

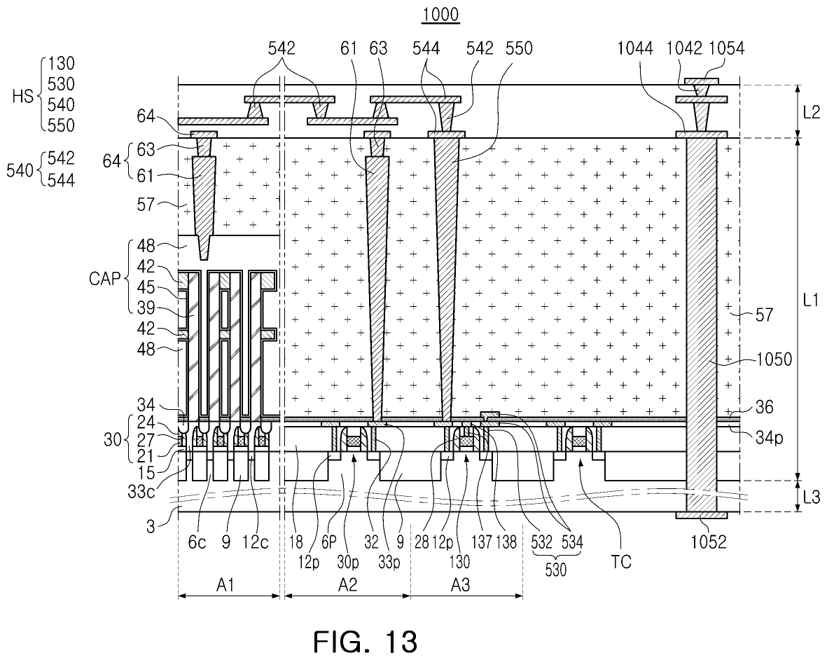

FIG. 13 is an enlarged view of the semiconductor device illustrated in FIG. 12. FIG. 13 is a vertical cross-sectional view corresponding to region A of FIG. 12. FIG. 13 illustrates the vertical reverse of region A of FIG. 12.

Referring to FIGS. 12 and 13, each of first to fourth semiconductor devices 810, 820, 830, and 840 may include a device layer L1, an interconnection layer L2, and a base layer L3. The device layer L1 and the interconnection layer L2 may include a configuration the same as or similar to that described with reference to FIG. 10. A backside layer (a lower portion of a substrate 3 illustrated in FIG. 13) of the substrate 3 may be referred to as the base layer L3.

In an example embodiment, a heating structure HS may further include a through-structure 1050 passing through the base layer L3 and the device layer L1 to be connected to the interconnection layer L2. For example, the through-structure 1050 may be electrically connected to upper contacts 1042 and upper interconnections 1044 disposed on the interconnection layer L2. In addition, the upper contacts 1042 and the upper interconnections 1044 may be electrically connected to a temperature control device TC through an upper structure 540 and a vertical structure 550. For example, the through-structures 1050 may be heated by the temperature control device TC, which may increase a temperature of a device region DR, and may be disposed to surround the device region DR in a plan view. The through-structures 1050 may be electrically insulated from a memory cell region A1 or a peripheral circuit region A2. For example, the through-structures 1050 may be isolated from a bit line structure 30 and a peripheral gate structure 30p without being electrically connected to the bit line structure 30 and the peripheral gate structure 30p.

The first to fourth semiconductor devices 810, 820, 830, and 840 may include dummy pads 1052 and 1054 connected to the through-structure 1050. In some example embodiments, the dummy pads 1052 and 1054 may be omitted.

In some example embodiments, the temperature control device TC may be disposed outside of the first to fourth semiconductor elements 810, 820, 830, and 840. For example, the temperature control device TC may be disposed in a buffer chip 805 or an interposer IP.

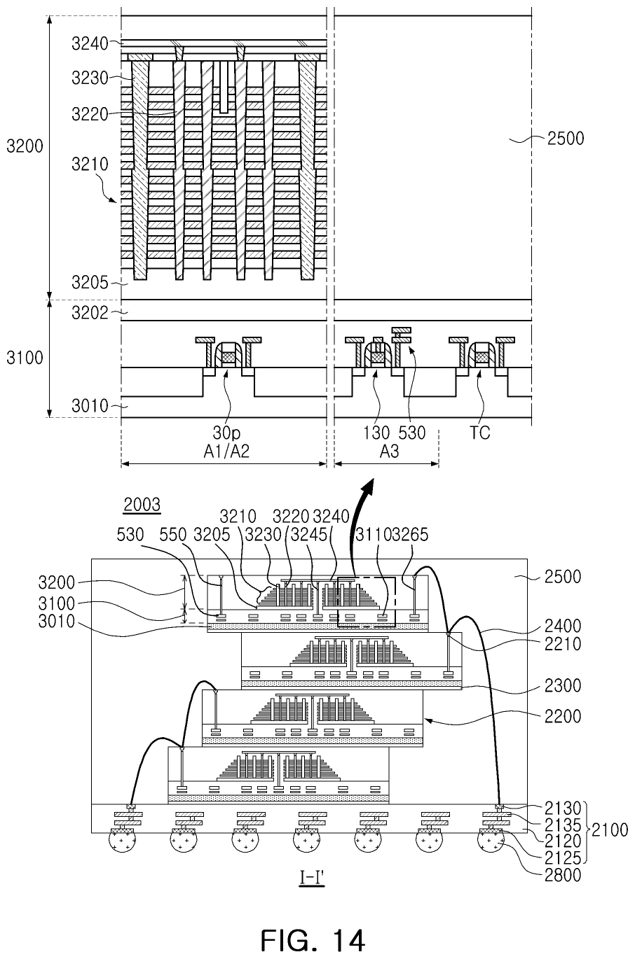

FIG. 14 is a vertical cross-sectional view of a semiconductor package including a semiconductor device according to an example embodiment.

Referring to FIG. 14, a semiconductor package 2003 may include a package substrate 2100, semiconductor devices 2200 disposed on the package substrate 2100, adhesive layers 2300 respectively disposed on lower surfaces of the semiconductor devices 2200, a connection structure 2400 electrically connecting the semiconductor devices 2200 and the package substrate 2100 to each other, and a molding layer 2500 covering the semiconductor devices 2200 and the connection structure 2400 on the package substrate 2100. In an example embodiment, the semiconductor devices 2200 may be NAND flash memory chips.

In the semiconductor package 2003, the package substrate 2100 may be a printed circuit board. The package substrate 2100 may include a package substrate body 2120, package upper pads 2130 disposed on an upper surface of the package substrate body 2120, lower pads 2125 disposed on a lower surface of the package substrate body 2120 or exposed through the lower surface, and internal interconnections 2135 electrically connecting the upper pads 2130 and the lower pads 2125 to each other in the package substrate body 2120. The upper pads 2130 may be electrically connected to the connection structures 2400.

Each of the semiconductor devices 2200 may include a semiconductor substrate 3010, and a first structure 3100 and a second structure 3200 sequentially stacked on the semiconductor substrate 3010. The first structure 3100 may have a peripheral circuit region including peripheral interconnections 3110. The second structure 3200 may include a common source line 3205, a gate stack structure 3210 disposed on the common source line 3205, memory channel structures 3220 and isolation structures 3230 passing through the gate stack structure 3210, bit lines 3240 electrically connected to the memory channel structures 3220, and gate connection interconnections electrically connected to word lines of the gate stack structure 3210. The first structure 3100 may be referred to as an interconnection layer, and the second structure 3200 may be referred to as a device layer. The semiconductor devices 2200 may further include a base 3202 disposed below the semiconductor substrate 3010. The base 3202 may be a passivation layer. The gate stack structure 3210 and the memory channel structures 3220 may form a memory cell.

Each of the semiconductor devices 2200 may include a through-interconnection 3245 electrically connected to the peripheral interconnections 3110 of the first structure 3100, the through-interconnection 3245 extending into the second structure 3200. The through-interconnection 3245 may pass through the gate stack structure 3210, and may be further disposed outside of the gate stack structure 3210. Each of the semiconductor devices 2200 may further include an input/output connection interconnection 3265 electrically connected to the peripheral interconnections 3110 of the first structure 3100, the input/output connection interconnection 3265 extending into the second structure 3200, and an input/output pad 2210 electrically connected to the input/output connection interconnection 3265.

As illustrated in the enlarged view, the semiconductor device 2200 may further include a peripheral gate structure 30p, a first lower structure 130, and a temperature control device TC. For example, the semiconductor substrate 3010 may have a memory cell region A1, a peripheral circuit region A2, and a heating region A3. The peripheral gate structure 30p may be disposed in the memory cell region A1 and the peripheral circuit region A2, and may vertically overlap the gate stack structure 3210. The peripheral gate structure 30p may be electrically connected to the peripheral interconnections 3110. The first lower structure 130 may be disposed in the heating region A3 and may be disposed to surround the device region (DR in FIG. 1) having the memory cell region A1 and the peripheral circuit region A2.

The semiconductor device 2200 may further include a second lower structure 530 disposed in the second structure 3200 and a vertical structure 550 electrically connected to the second lower structure 530. The first lower structure 130, the second lower structure 530, and the vertical structure 550 may have a structure the same as that described with reference to FIG. 10, and may be electrically connected to the temperature control device TC.

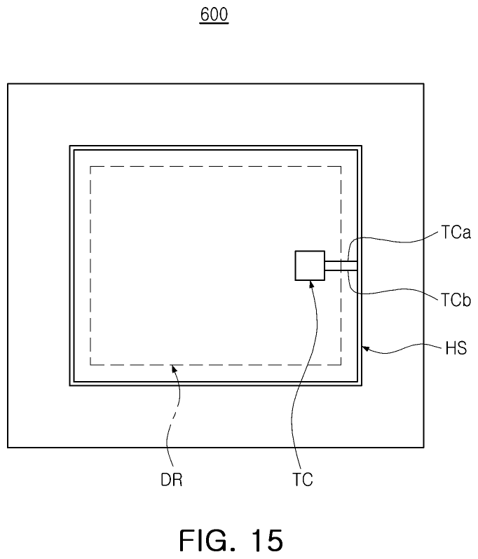

FIGS. 15 to 17 are plan views of a semiconductor device according to example embodiments.

Referring to FIG. 15, a semiconductor device 600 may include a heating structure HS surrounding a device region DR and a temperature control device TC electrically connected to the heating structure HS. In an example embodiment, the temperature control device TC may be disposed in the device region DR. For example, the temperature control device TC may be disposed in a peripheral circuit region A2.

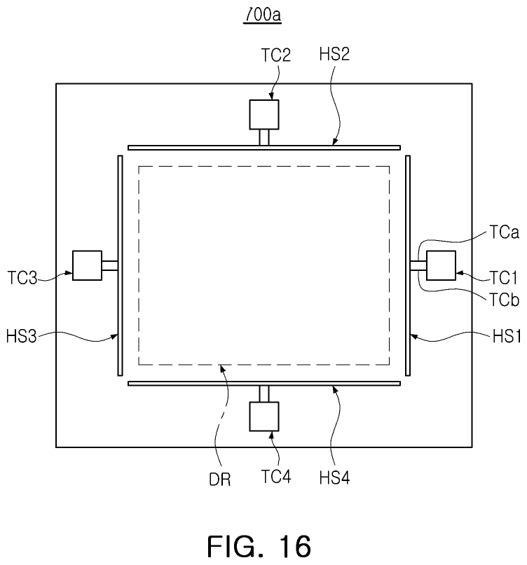

Referring to FIG. 16, a semiconductor device 700a may include heating structures surrounding a device region DR and temperature control devices electrically connected to the heating structures. In an example embodiment, the heating structures may include first to fourth heating structures HS1, HS2, HS3, and HS4. In an example embodiment, the first to fourth heating structures HS1, HS2, HS3, and HS4 may be spaced apart from each other, and are not electrically connected to each other. The temperature control devices may include first to fourth temperature control devices TC1, TC2, TC3, and TC4, and each of the temperature control devices may be electrically connected to a corresponding heating structure. Input/output terminals Tca and TCb of each of the first to fourth temperature control devices TC1, TC2, TC3, and TC4 may be connected to a corresponding heating structure.

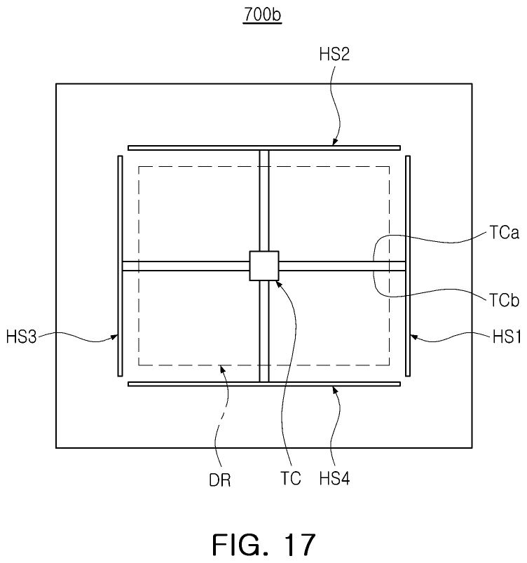

Referring to FIG. 17, a semiconductor device 700b may include heating structures surrounding a device region DR and a temperature control device TC electrically connected to the heating structures. In an example embodiment, the heating structures may include first to fourth heating structures HS1, HS2, HS3, and HS4, and each of the heating structures may be electrically connected to the temperature control device TC. For example, one temperature control device TC may be electrically connected to the first to fourth heating structures HS1, HS2, HS3, and HS4 through a plurality of input/output terminals TCa and TCb.

In some example embodiments, a structure of the heating structure HS illustrated in FIG. 9 may also be applied to the semiconductor devices of FIGS. 15 to 17. For example, a portion of the heating structures HS, illustrated in FIGS. 15 to 17, may extend across the device region DR in a horizontal direction in a plan view.

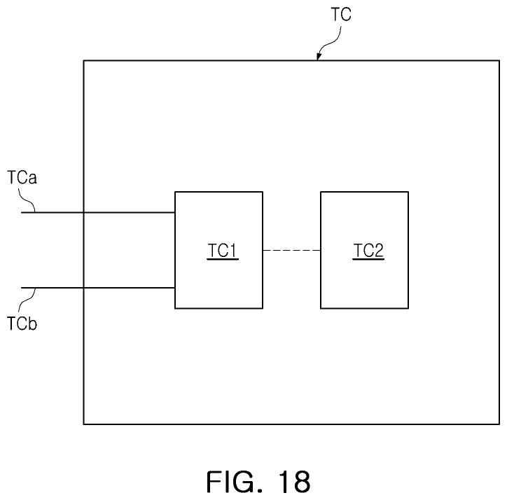

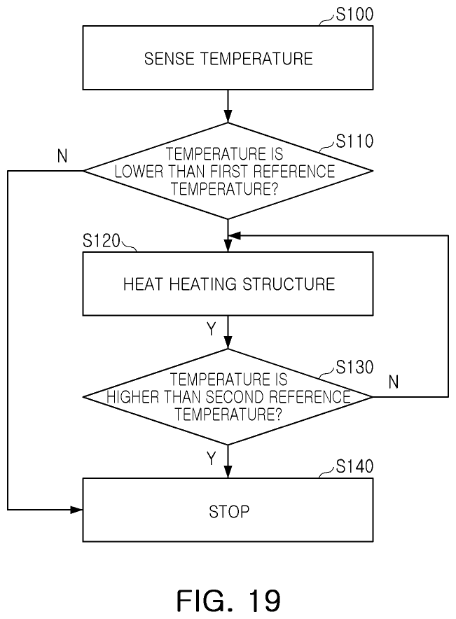

FIG. 18 is a schematic diagram of a temperature control device according to an example embodiment. FIG. 19 is a flowchart illustrating a temperature control method according to an example embodiment.

Referring to FIG. 18, the temperature control device TC may include a temperature sensor TC1 and a temperature controller TC2. The temperature sensor TC1 may be connected to input/output terminals TCa and TCb, and may be configured to measure a temperature of a heating structure HS. For example, the temperature sensor TC1 may transmit current to the input/output terminals TCa and TCb, and may measure temperature using a current difference or voltage difference between the terminals TCa and TCb.

In an example embodiment, the temperature sensor TC1 may include a proportional to absolute temperature (PTAT) current generator and a complementary to absolute temperature (CTAT) current generator.

A CTAT current may have a property in which a magnitude of current decreases with an increase in temperature, and a PTAT current may have a property in which a magnitude of current increases with an increase in temperature. Accordingly, the temperature of the heating structure HS may be measured using the PTAT current of the PTAT current generator and the CTAT current of the CTAT current generator. A temperature value measured by the temperature sensor TC1 may be transmitted to the controller, and may be used to determine whether to heat the heating structure HS.

Referring to FIG. 19, a temperature control method according to an example embodiment of the present inventive concept may include an operation of measuring a temperature of a heating structure HS (S100), an operation of determining whether the temperature of the heating structure HS is lower than a first reference temperature (S110), an operation of heating the heating structure HS by operating a temperature control device TC (S120), an operation of determining whether the temperature of the heating structure HS is higher than a second reference temperature (S130), and an operation of stopping an operation of the temperature control device TC (S140).

As described above, the operation of measuring the temperature of the heating structure HS (S100) may be performed by transmitting, by a temperature sensor TC1, current to the heating structure HS through input/output terminals TCa and TCb and measuring current or voltage between the input/output terminals TCa and TCb.

A temperature controller TC2 may receive a temperature value of the heating structure HS and determine whether the temperature of the heating structure HS is lower than the first reference temperature (S110).

In operation S110, when the temperature of the heating structure HS is lower than the first reference temperature, the temperature control device TC may be operated to heat the heating structure HS (S120). The heating structure HS may be disposed to surround a device region DR, such that temperature of the device region DR may be increased by heating the heating structure HS. Even while the heating structure HS is being heated, operation S100 of measuring the temperature of the heating structure HS may be continuously performed.

In operation S110, when the temperature of the heating structure HS is higher than the first reference temperature, the operation of the temperature control device TC may be stopped (S140).

The temperature controller TC2 may receive the temperature value of the heating structure HS and determine whether the temperature of the heating structure HS is higher than the second reference temperature (S130). The second reference temperature may be higher than or equal to the first reference temperature. In operation S130, when the temperature of the heating structure HS is higher than the second reference temperature, the operation of the temperature control device TC may be stopped (S140).

As is traditional in the field of the inventive concept, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

According to example embodiments of the present inventive concept, a heating structure may be disposed to surround a device region, and may heat the device region.

While the present inventive concept has been particularly shown and described with reference to embodiments thereof, it will be understood by those of ordinary skill in the art that various changes in form and detail may be made therein without departing from the spirit and scope of the present inventive concept as defined by the following claims.

What is claimed is:

1. A semiconductor device, comprising:
a substrate having a device region including a memory cell region and a peripheral circuit region, and a heating region surrounding the device region;
a heating structure disposed in the heating region of the substrate, the heating structure surrounding the device region in a plan view; and
a temperature control device electrically connected to the heating structure,
wherein the peripheral circuit region includes a peripheral gate structure,
the heating structure includes a first lower structure disposed at about a same level as the peripheral gate structure, and
the first lower structure includes a lower dielectric layer, and a conductive layer including polysilicon disposed on the lower dielectric layer.

2. The semiconductor device of claim 1, wherein the heating structure is electrically isolated from the peripheral gate structure.

3. The semiconductor device of claim 1, wherein
the peripheral gate structure includes a gate dielectric layer and a gate electrode disposed on the gate dielectric layer, and
a thickness of the lower dielectric layer is greater than a thickness of the gate dielectric layer.

4. The semiconductor device of claim 3, wherein
the gate electrode includes doped polysilicon, and
the conductive layer includes undoped polysilicon.

5. The semiconductor device of claim 1, wherein the conductive layer of the first lower structure includes a first conductive layer having a first conductivity type and a second conductive layer having a second conductivity type, different from the first conductivity type.

6. The semiconductor device of claim 1, wherein the lower dielectric layer of the first lower structure includes a first lower dielectric layer having a first thickness and a second lower dielectric layer having a second thickness, different from the first thickness.

7. The semiconductor device of claim 1, wherein
the heating structure further includes a second lower structure disposed on the first lower structure, and
the second lower structure includes lower interconnections including a metal material.

8. The semiconductor device of claim 7, wherein
the lower interconnections are vertically spaced apart from each other, and
the second lower structure further includes a lower contact electrically connecting the lower interconnections to each other.

9. The semiconductor device of claim 7, further comprising:
a peripheral interconnection disposed adjacent to the peripheral gate structure,
wherein at least one of the lower interconnections is disposed at about a same level as the peripheral interconnection.

10. The semiconductor device of claim 7, further comprising:
a device layer disposed on the substrate, the device layer including a memory cell; and
an interconnection layer vertically overlapping the device layer,
wherein the first lower structure and the second lower structure are disposed in the device layer.

11. The semiconductor device of claim 10, wherein the heating structure further includes an upper structure electrically connected to the second lower structure, the upper structure disposed in the interconnection layer, and a vertical structure electrically connecting the second lower structure and the upper structure to each other.

12. The semiconductor device of claim 11, wherein the upper structure extends across the device region in a horizontal direction in a plan view.

13. The semiconductor device of claim 10, further comprising:
a base layer vertically overlapping the device layer and the interconnection layer,
wherein the heating structure further includes a through-structure vertically passing through the base layer, the device layer, and the interconnection layer.

14. The semiconductor device of claim 7, further comprising:
a device layer disposed on the substrate, the device layer including a memory cell; and
an interconnection layer vertically overlapping the device layer,
wherein the first lower structure and the second lower structure are disposed in the interconnection layer.

15. The semiconductor device of claim 14, further comprising:
a vertical structure electrically connected to the second lower structure, the vertical structure passing through the device layer and the interconnection layer.

16. A semiconductor device, comprising:
a substrate having a device region including a memory cell region and a peripheral circuit region, and a heating region surrounding the device region;
at least one heating structure disposed in the heating region of the substrate, the at least one heating structure surrounding the device region in a plan view; and
at least one temperature control device electrically connected to the at least one heating structure,
wherein the peripheral circuit region includes a peripheral gate structure,
the peripheral gate structure includes a gate dielectric layer and a gate electrode disposed on the gate dielectric layer,
the at least one heating structure includes first lower structures disposed at a same level as the peripheral gate structure,
the first lower structures each include a lower dielectric layer and a conductive layer disposed on the lower dielectric layer, the conductive layer and the gate electrode including a same material, and
a thickness of a lower dielectric layer of at least one of the first lower structures is different from a thickness of the gate dielectric layer.

17. The semiconductor device of claim 16, wherein a portion of the at least one heating structure extends across the device region in a horizontal direction.

18. The semiconductor device of claim 17, wherein the at least one heating structure includes a plurality of heating structures, the at least one temperature control device includes a plurality of temperature control devices, and each heating structure is electrically connected to a corresponding temperature control device.

19. The semiconductor device of claim 17, wherein a portion of the at least one heating structure surrounds the device region.

20. A semiconductor device, comprising:
a substrate having a device region including a memory cell region and a peripheral circuit region, and a heating region surrounding the device region, wherein the peripheral circuit region includes a peripheral gate structure;
a heating structure disposed in the heating region of the substrate, the heating structure surrounding the device region in a plan view and including first lower structures disposed at a same level as the peripheral gate structure;
capping layers covering the first lower structures;
spacers covering side surfaces of the capping layers and the first lower structures;
first lower contacts passing through the capping layers, the first lower contacts electrically connected to the first lower structures;
a gate capping layer covering the peripheral gate structure;
a gate contact passing through the gate capping layer, the gate contact electrically connected to the peripheral gate structure; and
a temperature control device electrically connected to the heating structure,
wherein the first lower structures each include a lower dielectric layer, and a conductive layer including polysilicon disposed on the lower dielectric layer, and
the first lower contacts are electrically connected to the temperature control device and electrically isolated from the gate contact.
